(19) United States
(12) Patent Application Publication
(10) Pub. No.: US 2007/0052106 A1
(43) Pub. Date: Mar. 8, 2007

(54) Semiconductor device and method for fabricating the same

(75) Inventors: Kazumi Watase, Kyoto (JP); Akio Nakamura, Shiga (JP); Minoru Fujisaku, Kyoto (JP); Hiroki Naraoka, Osaka (JP); Takahiro Nakano, Kyoto (JP)

Correspondence Address: Jack Q. Lever, Jr.;McDERMOTT, WILL & EMERY L.L.P., 600 Thirteenth Street, N.W., Washington, DC, 20005-3096, US

(73) Assignee: MATSUSHITA ELECTRIC INDUSTRIAL CO., LTD.

(21) Appl. No.: 10/976,914

(22) Filed: Nov. 1, 2004

(30) Foreign Application Priority Data
Nov. 4, 2003 (JP) 2003-374108

(51) Int. Cl. H01L 23/48; H01L 21/4763

(52) U.S. Cl. 257/774; 438/629; 257/E23.02

(57) ABSTRACT

A first mark formed simultaneously with the process step for forming a layer of metal interconnects is partly exposed at two parallel side surfaces of the separated semiconductor device or one side surface thereof to have a rectangular shape. This allows the identification of the orientation and product information of the semiconductor device in a small semiconductor device.

### CROSS-REFERENCE TO RELATED APPLICATIONS

The disclosure of Japanese Patent Application No. 2003-374108 filed Nov. 4, 2003 including specification, drawing and claims is incorporated herein by reference in its entirely.

### BACKGROUND OF THE INVENTION

1. Field of the Invention

The present invention relates to a semiconductor device utilized for information communication equipment, business electronic equipment or the like and a method for fabricating the same, and more particularly relates to a semiconductor device in which a semiconductor substrate is covered with an insulating layer except for external connection terminals and a mark part is exposed at a part of the insulating layer located at a side surface of the device and a method for fabricating the same.

2. Description of Related Art

In recent years, with the diminishing size, increasing speed and increasing performance of electronic equipment, semiconductor devices have been desired to reduce their sizes and increase their speeds. As semiconductor devices for filling the need for such size reduction and speed-up, chip size packages (hereinafter, referred to as CSPs) have been developed in which semiconductor devices including packages each have the same size as a semiconductor chip.

FIGS. 9A and 9B are diagrams illustrating an example of a known CSP. FIG. 9A is a perspective view illustrating the same. The CSP (semiconductor device) 110 comprises a semiconductor substrate 101, an insulating layer 107 placed on the surface of the semiconductor substrate 101 formed with an integrated circuit, and a plurality of external connection terminals 106 projecting from the insulating layer 107. A product information mark 112 is printed on the surface of the semiconductor substrate 101 opposite to that provided with the insulating layer 107, and an orientation mark 113 is also printed thereon. The product information herein represents, for example, a product number, a lot number or the like of the semiconductor device 110.

The left diagram of FIG. 9B shows an assembly of semiconductor devices 110 at the wafer level and the right diagram thereof is an enlarged view partly showing a wafer. In the right diagram of FIG. 9B, reference numeral 111 denotes the assembly which is to be separated into individual semiconductor devices 110 along scribe lines 114 using dicing. The product information mark 112, such as a product number or a lot number of the semiconductor device 110, and the orientation mark 113 indicating the orientation of the semiconductor device 110 are printed before dicing. The orientation mark 113 indicating the orientation of the semiconductor device 110 is typically placed in the vicinity of a corner of the semiconductor device 110.

In the technique of Japanese Unexamined Patent Publication No. 2003-158217, as shown in FIG. 10, metal posts 206 are provided on a semiconductor substrate 201 to allow external connection and partly exposed at a side surface of a CSP (semiconductor device) 200, thereby providing an orientation mark 220 indicating the orientation of the semiconductor device 200. FIG. 10A is a plan view showing the separated semiconductor devices 200 after the completion of dicing. FIG. 10B is a side view showing the semiconductor device 200 when viewed from the right side of FIG. 10A.

### SUMMARY OF THE INVENTION

However, the latter known semiconductor device is formed only with the orientation mark. Therefore, it is difficult to ensure product traceability. In addition, since an electrical test is used even when the semiconductor device is to be distinguished from the other products of the same length and width, it is difficult to find the semiconductor device out of a product group mixed with one or more other types of products. Furthermore, it is very difficult to utilize the metal posts to indicate product information, because the metal posts are relatively large for the size of the semiconductor device. Furthermore, the metal posts constituting the orientation marks are likely to peel off and thus be lost, because no insulating layer exists on the uppermost part of the orientation mark.

In the former known semiconductor device, an indication mark is formed by back-grinding the exposed surface of the semiconductor substrate opposite to the surface thereof formed with external connection terminals and employing an ink printing technique using an organic material or a laser cutting technique. This indication mark permits the identification of the product information, such as the product number and lot number of the semiconductor device, and the orientation of the semiconductor device (showing the reference point of an external connection terminal array). Alternatively, a method can also be utilized in which the external connection terminals are asymmetrically placed to identify the orientation of the semiconductor device. It is typical that in the ink printing and laser cutting, numbers or alphabet letters each with a character width of 100 μm or more are formed to enhance viewability and for the mark indicating the orientation of the semiconductor device, a circle with a diameter of 500 μm or more is formed in the vicinity of a corner of the semiconductor device. Furthermore, it is typical that the external connection terminals are asymmetrically arrayed without the formation of some of peripheral external connection terminals. However, in the case of a semiconductor device having a small length and width, there is no method for forming a mark indicating its product number and lot number and a mark indicating its orientation, except to form only part of the product number or the lot number or to form no mark indicating the orientation. The reason for this is that a region of the semiconductor device to be formed with the mark is limited. For a semiconductor device with a size of 1 mm or less, it is difficult to even form the mark indicating the product number and lot number and the mark indicating the orientation of the semiconductor device with stable quality. When the product number and lot number of the semiconductor device is only partly formed or cannot be formed, it is difficult to ensure product traceability. In addition, since an electrical test is used even when the semiconductor device is to be distinguished from the other products of the same length and width, it is difficult to find the semiconductor device out of a product group mixed with one or more other types of products. When no mark indicating the orientation of the semiconductor device can be formed but the external connection terminals must symmetrically be placed due to limitations on the number of the external connection terminals and layout design, it is difficult to identify the orientation of the semiconductor device. For example, if the semiconductor devices are shipped using a tray or embossed carrier tape while being misoriented, this causes assembly failures during the assembling of the semiconductor devices or electrical defects after the assembling. Such defects more remarkably occur with size reduction in CSP, because the ink printing or laser cutting becomes more difficult.

The present invention is made to solve the above-described conventional problems, and an object thereof is to provide a semiconductor device which allows its orientation and product information to be easily identified when separated from a wafer into an individual piece and a method for fabricating the same.

A semiconductor device of the present invention comprises: a semiconductor substrate; an element electrode formed on the top surface of the semiconductor substrate; a first insulating layer formed on the semiconductor substrate to have an opening at least on the element electrode; a metal interconnect layer formed to cover the top surface of the element electrode and a part of the first insulating layer to extend from the element electrode partway across the first insulating layer; a second insulating layer formed above the semiconductor substrate with the exception of the surfaces of parts of the metal interconnect layer; and external connection terminals formed on parts of the metal interconnect layer exposed from the second insulating layer, wherein a plurality of mark parts made of metal are exposed at one or some of the side surfaces of the semiconductor device generally vertical to the top surface of the semiconductor substrate, the parts of the side surfaces of the semiconductor device being composed of the second insulating layer.

In one embodiment, the plurality of mark parts may constitute identification symbols of the semiconductor device.

In one embodiment, the mark parts may be exposed at two of the side surfaces of the semiconductor device parallel to each other.

In one preferred embodiment, an extension may be provided at the side surfaces of the semiconductor device to project vertically to the side surfaces, and the mark part may be exposed also at the surface of the extension vertical to the side surfaces of the semiconductor device.

In one preferred embodiment, the mark part may electrically be connected to the element electrode.

In one preferred embodiment, at least some of the mark parts may form layered metal parts which are different from one another in distance from the top surface of the semiconductor device.

A method for fabricating a semiconductor device of the present invention comprises: the step S of forming a first insulating layer on the top surface of a semiconductor substrate in the form of a wafer on which an element electrode is formed and removing a part of the first insulating layer located on the element electrode; the step T of forming a metal interconnect layer to cover the top surface of the element electrode and a part of the first insulating layer; the step U of forming a metal layer serving as mark parts to each extend across a scribe line to the ends of the adjacent element regions of the semiconductor substrate; the step V of, after the steps T and U, forming a second insulating layer on the entire surface region of the semiconductor substrate and removing parts of the second insulating layer located on the surfaces of parts of the metal interconnect layer; the step W of forming external connection terminals on the surfaces of the parts of the metal interconnect layer exposed by removing the parts of the second insulating layer; and the step X of cutting the semiconductor substrate along each said scribe line to obtain individual semiconductor devices.

In one embodiment, in the step U, each said metal layer may be formed to expose a plurality of said mark parts at at least one cut surface of the semiconductor device separated in the step X.

In one embodiment, the step T may be carried out simultaneously with the step U.

In one preferred embodiment, the step X may comprise: the step X1 of cutting the second insulating layer along the scribe line at a first width until the metal layer is exposed; and the step X2 of cutting, at a second width narrower than the first width, along the center line of the exposed surface of the metal layer obtained by cutting the second insulating layer at the first width until the semiconductor substrate is cut through.

In one preferred embodiment, in the steps U and V, a plurality of metal layers may be formed to interpose the second insulating layer between the adjacent metal layers.

### BRIEF DESCRIPTION OF THE DRAWINGS

FIG. 1A is a perspective view showing a semiconductor device according to a first embodiment, FIG. 1B is a side view showing the same, and FIG. 1C is a cross-sectional view taken along the line A-A shown in FIG. 1A.

FIG. 2 is a cross-sectional view showing the first half of process steps for fabricating the semiconductor device according to the first embodiment.

FIG. 3 is a cross-sectional view showing the latter half of process steps for fabricating the semiconductor device according to the first embodiment.

FIG. 4A is a cross-sectional view showing a semiconductor device according to a second embodiment.

FIG. 4B is a cross-sectional view showing a semiconductor device according to a third embodiment.

FIG. 4C is a side view showing a semiconductor device in which both first marks and second marks are formed as described in the second and third embodiments, respectively.

FIG. 5 is a cross-sectional view showing a semiconductor device according to a fourth embodiment.

FIG. 6A and FIG. 6B are cross-sectional views showing some of process steps for fabricating a semiconductor device according to a fifth embodiment, and FIG. 6C is a perspective view showing the semiconductor device according to the fifth embodiment.

FIG. 7A is a perspective view showing a semiconductor device according to a sixth embodiment, FIG. 7B is a side view showing the same, and FIG. 7C is a cross-sectional view taken along the line B-B shown in FIG. 7A.

FIG. 8A through 8D are cross-sectional views showing some of process steps for fabricating the semiconductor device according to the sixth embodiment.

FIG. 9A is a perspective view showing a known semiconductor device in which printing is applied on a semiconductor substrate.

FIG. 9B is a plan view showing an assembly of a plurality of semiconductor devices.

FIG. 10A is a plan view showing the known semiconductor device after completion of dicing, and FIG. 10B is a side view showing the same.

### DETAILED DESCRIPTION OF THE INVENTION

Embodiments of the present invention will now be described in detail with reference to the drawings.

### Embodiment 1

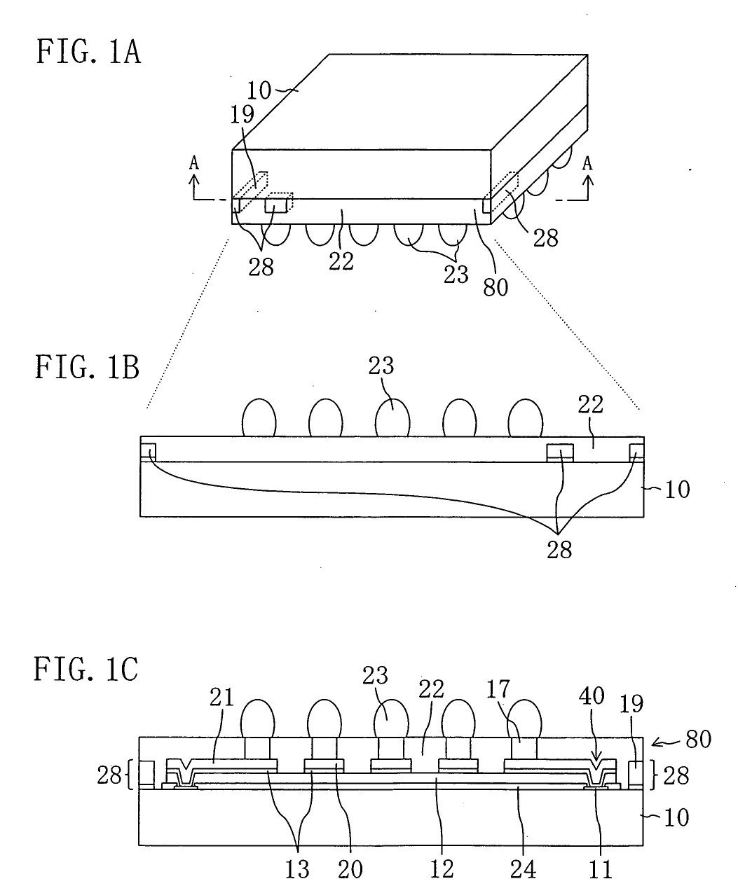

FIG. 1A is a perspective view showing a semiconductor device according to a first embodiment. FIG. 1B is a diagram showing the front side of FIG. 1A upside down. FIG. 1C is a cross-sectional view taken along the line A-A shown in FIG. 1A. In cross-sectional views described here and later, hatching is not given for the sake of the viewability of the drawings.

A semiconductor device of the present invention represents a CSP and is provided with a second insulating layer 22 on the surface of a semiconductor substrate 10 formed with a semiconductor integrated circuit composed of semiconductor elements such as transistors. The semiconductor device further comprises a plurality of external connection terminals 23, 23, . . . projecting from the surface of the second insulating layer 22. A plurality of mark parts 28, 28, 28 made of metal are exposed at parts of the second insulating layer 22 located on the side surfaces 80 of the semiconductor device. These mark parts 28, 28, 28 constitute the identification symbols of the semiconductor device. For example, different sizes, shapes and layouts of mark parts 28, 28, 28 indicate different production numbers, product types and lot numbers of semiconductor devices. The mark parts 28, 28, 28 also indicate the orientation of the semiconductor device (for example, the orientation in which the semiconductor device is assembled).

The semiconductor device of the present invention will be described in more detail. The surface of the semiconductor substrate 10 formed with the integrated circuit is also formed with element electrodes 11. A passivation film 24 and a first insulating layer 12 are formed in this order substantially on the entire surface of the semiconductor substrate 10 with openings 40 provided on the element electrodes 11. The passivation film 24 is made of silicon nitride, silicon oxide or the like. A thin metal layer 13 and a layer of first metal interconnects 21 are stacked in this order over the element electrodes 11 exposed at the openings 40 and parts of the first insulating layer 12. The thin metal layer 13 and the metal interconnects are also formed on other parts of the first insulating layer 12, thereby constituting lands 20. Furthermore, a second insulating layer 22 is formed on the entire surface region of the substrate 10 with the exception of parts of the first metal interconnects 21 and lands 20. Second metal interconnects 17 serving as posts are formed on the parts of the first metal interconnects 21 formed with no second insulating layer 22 and the lands 20. The top surfaces of the second metal interconnects 17 are generally flush with the second insulating layer 22 and exposed from the second insulating layer 22. External connection terminals 23 are formed on the second metal interconnects 17 to project generally hemispherically, respectively.

The mark parts 28 are first marks 19 made of the same metal as the thin metal layer 13 and the second metal interconnect 17. In this case, the second insulating layer 22 is placed on the first marks 19. Since the generally-rectangular-parallelepiped-shaped mark parts 28 are therefore embedded in the second insulating layer 22 and only one surface of each mark part 28 is exposed, each mark part 28 is not likely to drop off from the semiconductor device. Furthermore, two mark parts 28 and 28 are exposed at two parallel sides of the semiconductor device, respectively.

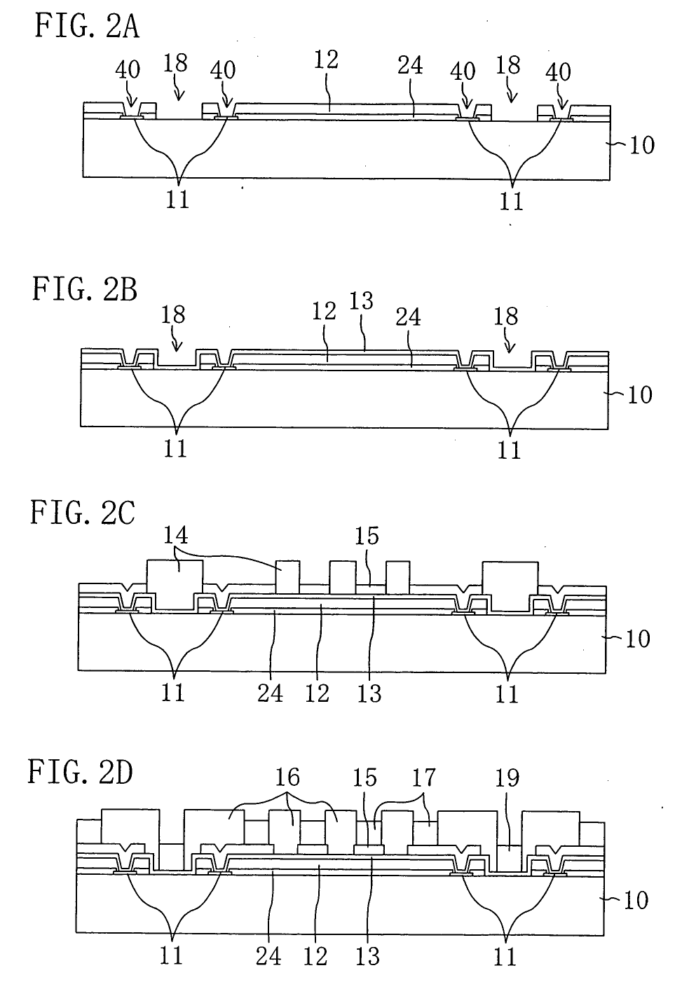

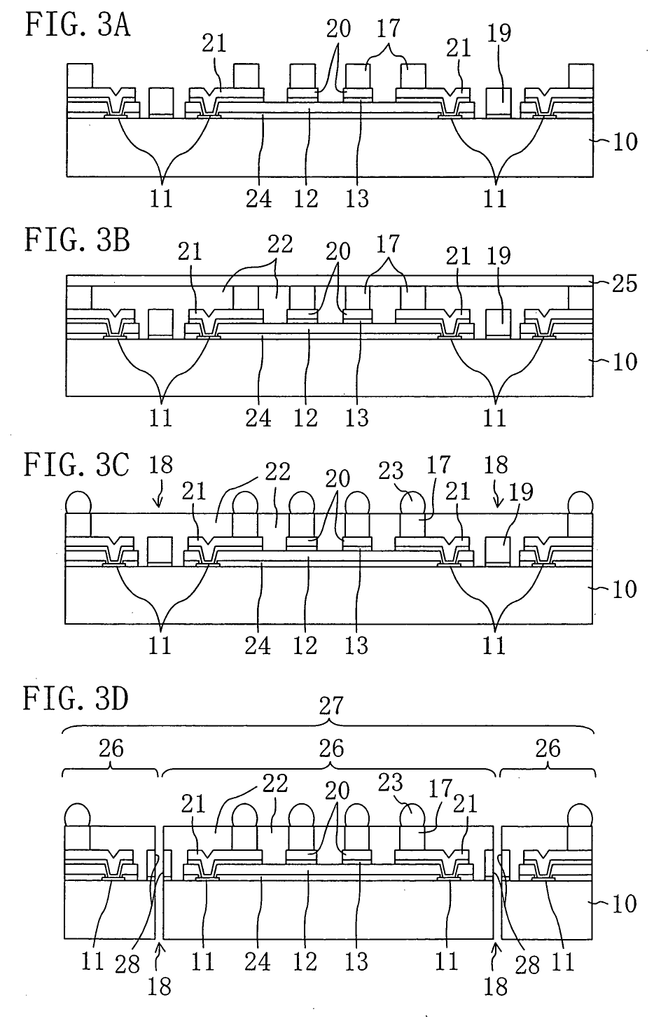

Next, a description will be given of a fabrication method for the semiconductor device of this embodiment with reference to the cross-sectional views shown in FIGS. 2A through 3D.

First, a semiconductor substrate 10 is prepared which is in the form of a wafer and has a semiconductor integrated circuit composed of elements such as transistors or capacitors. Element electrodes 11 have also been formed on the top surface of the semiconductor substrate 10. As shown in FIG. 2A, a passivation film 24 is formed on the semiconductor substrate 10. Then, its top surface is coated with a photosensitive insulating material by spin coating, dried and successively exposed to light and developed. Parts of the passivation film 24 located on the element electrodes 11 above the semiconductor substrate 10 are selectively removed. A first insulating layer 12 is thereby formed to expose the element electrodes 11 through openings 40. A polymer such as an ester linkage type polyimide or an acrylate epoxy is preferably used for the photosensitive first insulating layer 12. However, the first insulating layer 12 can be formed from any photosensitive insulating material. Alternatively, a material previously formed like a film may be employed as the first insulating film 12. In this case, the first insulating layer 12 is bonded to the semiconductor substrate 10, and formed with openings 40 by exposure and development to expose the element electrodes 11. The first insulating layer 12 need not be formed on scribe lines 18 and the outer ends of element regions adjacent to the scribe lines 18. Thus, in this embodiment, it is not formed thereon.

Next, as shown in FIG. 2B, a thin metal layer 13 is formed on the entire surfaces of the first insulating layer 12 and element electrodes 11 exposed through the openings 40 by any one of thin film formation techniques including sputtering, vacuum deposition, Chemical Vapor Deposition (CVD), and electroless plating. The thin metal layer 13 is obtained by stacking, for example, an approximately 0.2-μm-thick TiW film and an approximately 0.5-μm-thick Cu film in this order.

Next, as shown in FIG. 2C, the entire surface region of the semiconductor substrate 10 is coated with a positive photoresist film or a negative photoresist film by spin coating and dried. Then, a pattern of first plating resists 14 is formed from the photoresist film by known exposure and development techniques. Thereafter, a thick metal layer 15 is selectively formed on parts of the thin metal layer 13 exposed from the first plating resist 14 by using a thick film formation technique such as electrolytic plating. In this embodiment, a thick metal layer 15 made of an approximately 5-μm-thick Cu film is selectively formed. The thick metal layer 15 is later formed into first metal interconnects 21 and lands 20.

Next, as shown in FIG. 2D, the first plating resists 14 are dissolved and removed and the entire surface region of the semiconductor substrate 10 is coated with another positive photoresist film or negative photoresist film and dried. Then, a pattern of second plating resists 16 is formed from the photoresist film by known exposure and development techniques. In this case, a material previously formed like a film may be employed as the photosensitive second plating resists 16. Thereafter, second metal interconnects 17 are formed on parts of the thick film metal layer 15 exposed from the second plating resists 16 by again using a thick film formation technique such as electrolytic plating. At the same time, first marks 19 made of a metal layer are selectively formed on parts of the thin metal layer 13 located on the scribe lines 18 and the parts of the element regions continuous with the scribe lines 18. The part of the element region continuous with the scribe line 18 on which the first mark 19 is formed represents a part of the element region forming the periphery of the semiconductor substrate when the semiconductor devices are individually separated along the scribe lines 18. Metal material employed for the second metal interconnects 17 and the first marks 19 may be either the same metal material as or different one from the thick metal layer 15. In this embodiment, the same metal material, i.e., Cu is employed.

In this process step, the use of a thick film formation technique such as electrolytic plating allows the simultaneous formation of the second metal interconnects 17 and the first marks 19. Thus, the first marks 19 can selectively be formed, for example, to have a thickness of approximately 100 μm. In the above process step, the first marks 19 are formed simultaneously through a normal photolithography process and a normal thick film formation process such as electrolytic plating for forming the second metal interconnects 17. Hence, the number of the photolithography processes and thick film formation processes such as electrolytic plating does not differ from when no first marks 19 is formed. Furthermore, since the first marks 19 are formed by the photolithography process, this permits the formation of the first marks 19 with high positional accuracy and high dimensional accuracy as long as the first marks 19 are formed in possible sites to have formable shapes.

After the formation of the second metal interconnects 17 and first marks 19, as shown in FIG. 3A, the second plating resists 16 are dissolved and removed and an etchant that can dissolve and remove the thin metal layer 13 is applied to exposed parts of the thin metal layer 13. Etching is performed on the entire region of the semiconductor substrate, for example, by using a ferric chloride solution for the thin Cu film and aqueous hydrogen peroxide for the TiW film. Thus, the exposed parts of the thin metal layer 13 having a smaller thickness than the other layers is removed, and the first metal interconnects 21 and lands 20 both formed from the thick metal layer 15 and the second metal interconnects 17 are left. This process step provides the formation of predetermined first metal interconnects 21 and lands 20 for forming external connection terminals above the semiconductor substrate 10. For example, if the first metal interconnects 21 formed by electrolytic plating each have a thickness of 5 μm, they can be formed such that Line/Space=20/20 μm.

Next, as shown in FIG. 3B, a second insulating layer 22 is formed on the entire surface region of the semiconductor substrate 10 by using a sealing die 25. At this time, in order to expose the top surfaces of the second metal interconnects 17, the sealing die 25 contacts the top surfaces of the second metal interconnects 17. The second insulating layer 22 is formed, for example, using an epoxy resin to have a thickness of 50 through 100 μm. In this case, the second insulating layer 22 covers and thus protects the top and side surfaces of the first metal interconnects 21, lands 20 and first marks 19 and the side surfaces of the second metal interconnects 17. Since the first marks 19 are wholly covered with the second insulating layer 22, this can ensure a sufficiently large adhesive strength between the first marks 19 and the second insulating layer 22.

Next, as shown in FIG. 3C, the top surfaces of the second metal interconnects 17 are subjected to an oxidation prevention process, and thereafter external connection terminals 23 are formed thereon. The external connection terminals 23 are balls or bumps. Either printing or plating may be used to form the bumps. The oxidation prevention process is implemented, for example, by forming an (unshown) Ni film with a thickness of approximately 3 μm using electrolytic plating.

Furthermore, as shown in FIG. 3D, an assembly 27 comprising a plurality of semiconductor devices 26, which is obtained by completing the above process steps, is cut along the scribe lines 18 by dicing. Thus, the plurality of semiconductor devices are individually separated from one another. For example, when the assembly 27 is subjected to dicing along each scribe line 18 having a width of 100 μm by using a 30-μm-wide dicing blade, 35-μm-wide remaining regions of the scribe line 18 are formed on both sides of the cut line. In this manner, semiconductor devices are individually separated from one another. In this case, the first mark 19 formed on each scribe line 18 is also cut and divided together with the second insulating layer 22 and the semiconductor substrate 10. A part of the first mark 19 remains in the remaining region of the scribe line 18 and serve as a part of a package.

Each first mark 19 is formed on a region of the semiconductor substrate 10 extending across the scribe line 18 to the peripheries of the adjacent element regions. The first mark 19 results in the two following cases: the case where the first mark 19 remains in the opposed side surfaces of two adjacent semiconductor devices 26 and 26 with the scribe line 18 interposed therebetween and is exposed as mark parts 28 and 28 at both the opposed side surfaces; and the case where the first mark 19 remains only in a side surface of one of two adjacent semiconductor devices 26 and 26 and is exposed as a mark part 28. This embodiment corresponds to the former case. In this embodiment, two mark parts 28 and 28 of the same shape and dimensions are formed in the side surfaces of two adjacent semiconductor devices 26 and 26. Furthermore, in this embodiment, the mark parts 28 and 28 of the same shape and layout are formed at the two parallel side surfaces 80 and 80 of the semiconductor device 26. Thus, when a mark part 28 is inspected by an inspecting device, it can be observed by viewing the semiconductor device 26 from at least two sides independent of the orientation of the semiconductor device 26.

Furthermore, the mark part 28 is covered with the semiconductor substrate 10 and the second insulating layer 22 with the exception of the exposed surface thereof. This prevents the mark parts 28 from peeling off and dropping off from the side surfaces of the semiconductor devices 26 separated from one another by dicing and can reduce metal burrs and metal waste due to dicing. Although in this embodiment each mark part 28 is rectangular, it may have an arbitrary shape that can be formed in the photolithography process. In this case, the arbitrary shape must be a shape that can be identified by a visual inspection and an inspecting device. In addition, in all the semiconductor devices 26, the mark parts 28 may be formed anywhere in the side surfaces 80 of each semiconductor device 26.

In an alternative to the above embodiment, the first marks 19 are formed not simultaneously with the formation of the second metal interconnects 17 but simultaneously with the formation of the thick metal layer 15. In this case, each first mark 19 has a thickness of approximately 5 μm. Since also in this case the number of fabrication processes is not increased, the cost for making first marks 19 is not substantially increased. Furthermore, each first mark 19 can be formed with high positional accuracy and high dimensional accuracy.

### Embodiment 2

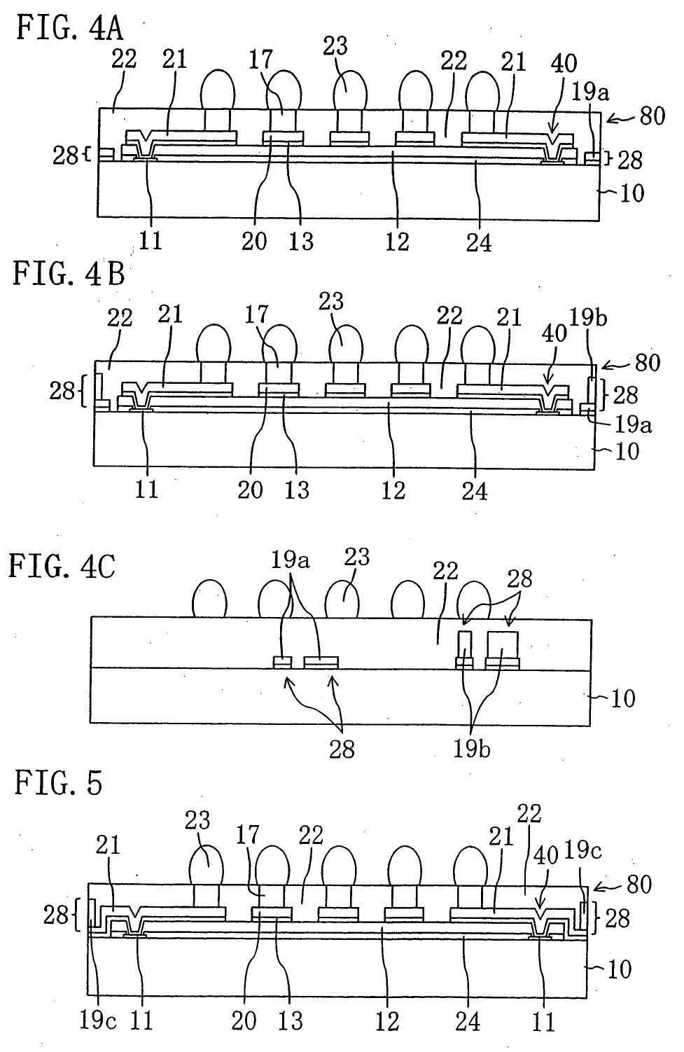

FIG. 4A is a cross-sectional view showing a semiconductor device according to a second embodiment. In this embodiment, first marks 19a are formed simultaneously with the formation of a layer of the first metal interconnects 21. Therefore, the first mark 19a is thinner than the first mark 19 of the first embodiment. The other structures, fabrication process steps, and effects and benefits are the same as in the first embodiment.

### Embodiment 3

FIG. 4B is a cross-sectional view showing a semiconductor device according to a third embodiment. In this embodiment, a second mark 19b is formed on each first mark 19a of the second embodiment simultaneously with the formation of the second metal interconnect 17. This can complicate the shape of each mark part 28 exposed at the associated side surface 80 of the semiconductor device 26, and allows a lot of information to be incorporated into the mark part 28 even when a small number of marks are provided. The other structures, fabrication process steps, and effects and benefits are the same as in the first embodiment.

FIG. 4C is a side view showing a semiconductor device in which both the first marks 19a and second marks 19b as described in the second and third embodiments are formed. As in this case, the different types of marks 19, 19a and 19b of the first through third embodiments may be formed as mixed in a single semiconductor device.

### Embodiment 4

FIG. 5 is a cross-sectional view showing a semiconductor device according to a fourth embodiment. In this embodiment, each first mark 19c is electrically connected through the first metal interconnect 21 to the element electrode 11. More particularly, each first mark 19c is formed on the first metal interconnect 21 which has been formed to extend across the boundary between the element region and the scribe line 18 to the scribe line 18. The other structures, fabrication process steps, and effects and benefits are the same as in the first embodiment.

With the structure of this embodiment, heat generated in the integrated circuit of the semiconductor substrate 10 is conveyed through the first metal interconnect 21 to the first mark 19c and then released therefrom to the outside. Since the electrical connection of the first mark 19c with the element electrode 11 provides an excellent heat transfer capability, it can be said that the semiconductor device of this embodiment has an efficient heat dissipating mechanism.

Furthermore, the first mark 19c can be used as a test terminal for electrically testing a PCM (Process Control Module) for checking a wafer-level CSP for the connection reliability between the first metal interconnect 21 and the element electrode 11 and the interconnect reliability of the first metal interconnect 21 in a CSP fabricating process. This eliminates the need for additionally forming external connection terminals 23 necessary for electrically checking the CSP for the connection reliability between the first metal interconnect 21 and the element electrode 11 and the interconnect reliability of the first metal interconnect 21, does not exert an influence on the number of the external connection terminals 23, and thus is advantageous in the layout design.

In this embodiment, the first marks 19c are exposed not to the opposed circuit board on which the semiconductor device is to be mounted, but at the side surfaces 80 of the semiconductor device. Therefore, none of electrical problems, such as short circuit and miswiring, is caused.

### Embodiment 5

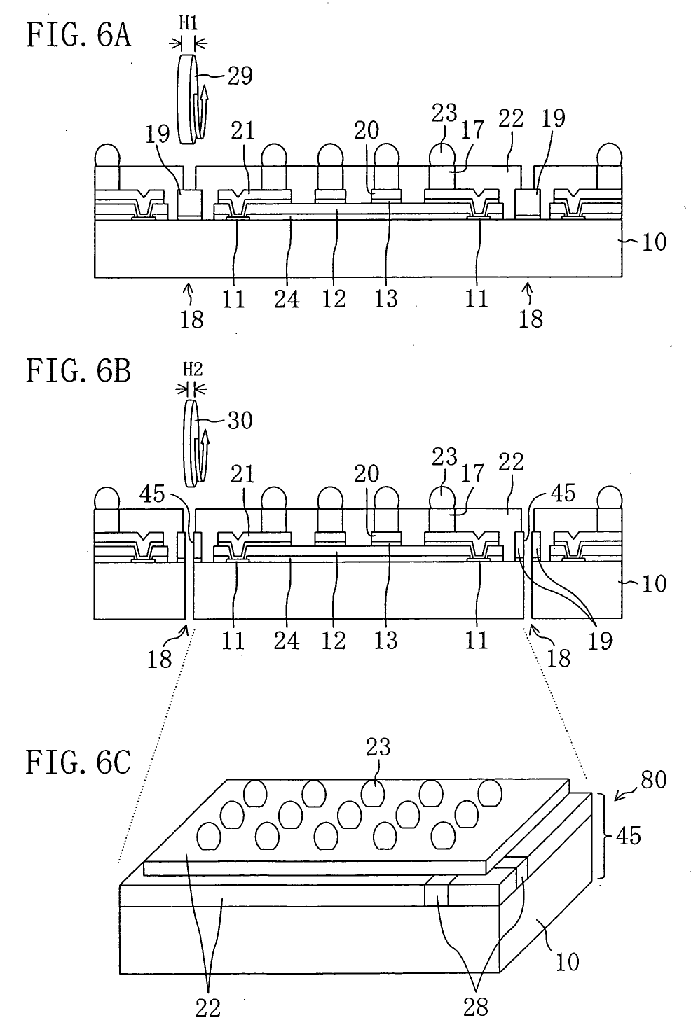

FIG. 6C is a perspective view showing a semiconductor device according to a fifth embodiment, and FIGS. 6A and 6B are cross-sectional views showing some of semiconductor device fabricating process steps.

First, the semiconductor device fabrication process will be described. Also in this embodiment, the first process step through the process step shown in FIG. 3C of the process steps described in the first embodiment are likewise carried out. This embodiment is different from the first embodiment in a cutting process step that is the subsequent process step.

In the cutting process step, as shown in FIG. 6A, the second insulating layer 22 is first diced, using a first dicing blade 29 with a first width H1, from its top surface on which external connection terminals 23 are formed until the top surface of a metal layer of which the first mark 19 is formed is exposed.

Then, as shown in FIG. 6B, the exposed metal layer is diced along the center line of its top surface (cut surface), using a second dicing blade 30 with a second width H2 narrower than the first width H1, until the semiconductor substrate 10 is cut through. Since such two kinds of dicing blades 29 and 30 with different widths are used to cut the wafer, an extension 45 is formed at the side surfaces 80 of the semiconductor device.

As shown in FIG. 6C, each mark part 28 is exposed also at the surface of the extension 45 vertical to a side surface 80 of the semiconductor device, i.e., the surface of the extension 45 parallel to the top surface of the semiconductor device. Hence, the mark part 28 can easily be recognized from two orthogonal directions, i.e., from above and side in FIG. 6C. Therefore, the viewability of the mark part 28 is significantly enhanced as compared with the above embodiments.

In this embodiment, for example, when the first dicing blade 29 has a width of approximately 50 μm and the second dicing blade 30 with a width of approximately 30 μm is used for the dicing of the first mark 19 and the semiconductor substrate 10, a extension 45 is formed at the side surfaces of the semiconductor device 26 to have an extension width of approximately 10 μm from each side surface of the second insulating layer 22.

### Embodiment 6

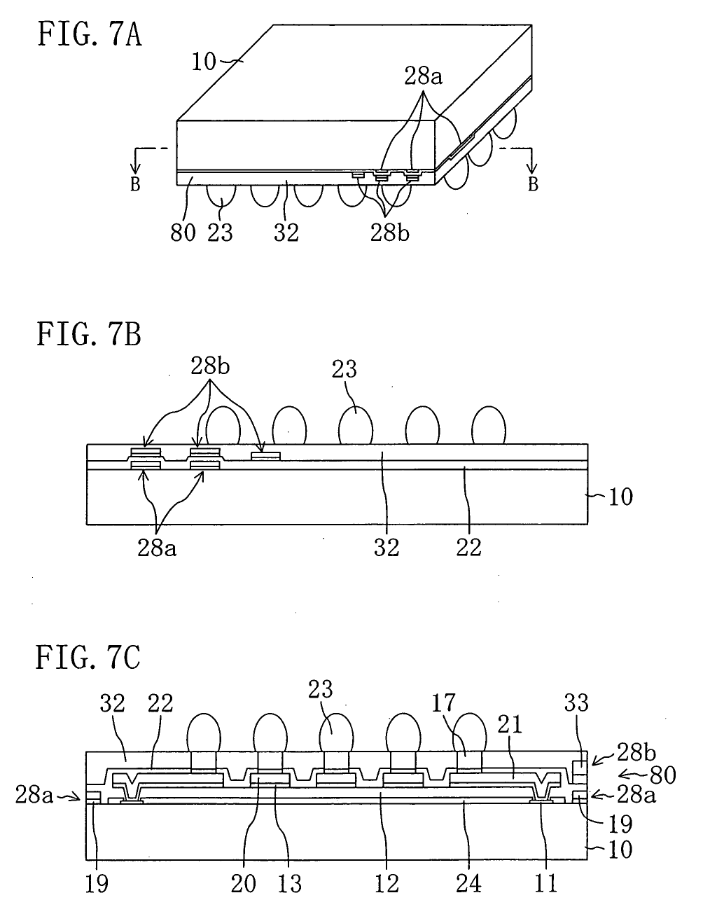

FIG. 7A is a perspective view showing a semiconductor device according to a sixth embodiment. FIG. 7B is a diagram showing the front side of FIG. 7A upside down. FIG. 7C is a cross-sectional view taken along the line B-B shown in FIG. 7A. In this embodiment, layered mark parts 28a and 28b are formed in the thickness direction of the semiconductor device with the second insulating layer 22 interposed therebetween. The mark part 28a is first formed of the first mark 19a, and the mark part 28b is formed by placing the second insulating layer 22 on the first mark 19a and further placing a second mark 33 thereon. Therefore, the mark part 28a is different from the mark part 28b in distance from the top surface of the semiconductor substrate 10. Since the mark parts 28a and 28b are thus stacked to form a multilayer structure, this permits the formation of marks indicating the orientation of the semiconductor device and a larger amount of product information (identification information). For the product information, in particular, a lot number can carry contents including the year of manufacture, the month of manufacture, and the week of manufacture. The indication of such a larger amount of product information can ensure more accurate product traceability. Furthermore, this mark may be used as a bar code.

A method for fabricating a semiconductor device of this embodiment will be described hereinafter.

First, also in this embodiment, the process steps shown in FIGS. 2A through 2C of the process steps in the above first embodiment are performed substantially in the same manner. However, unlike the first embodiment, the first marks 19a are formed not simultaneously with the formation of the second metal interconnects 17 but simultaneously with the formation of the thick metal layer 15.

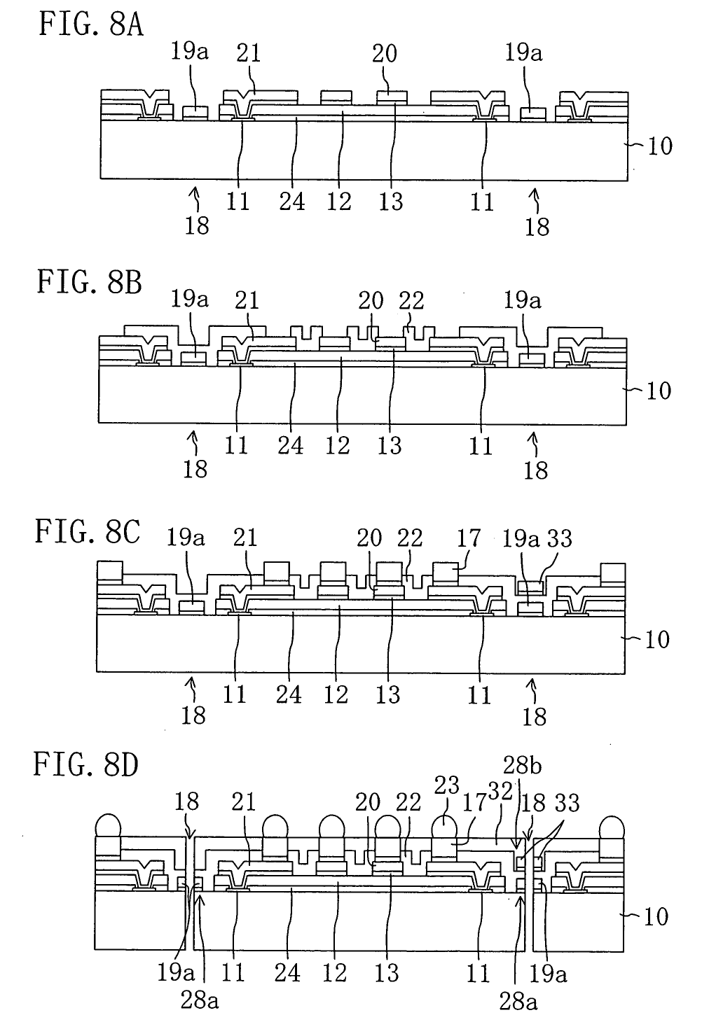

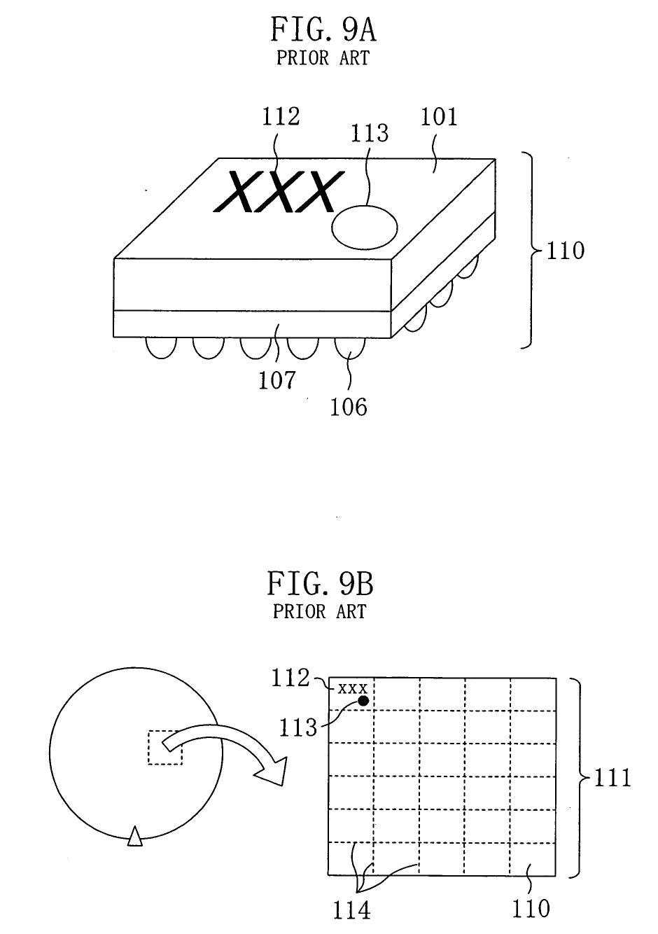

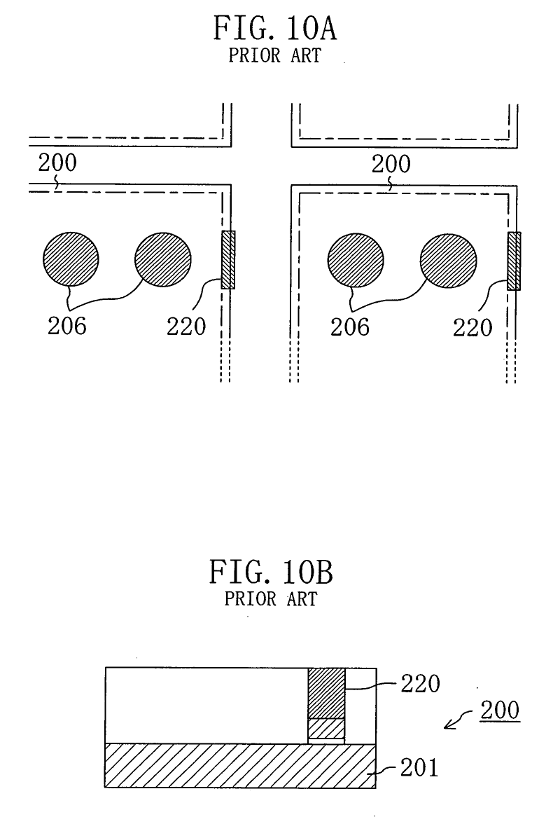

Next, as shown in FIG. 8A, the first plating resists 14 are dissolved and removed and the entire surface region of the semiconductor substrate 10 is coated with another positive photoresist film or negative photoresist film and dried. Then, a pattern of second plating resists is formed from the photoresist film by known exposure and development techniques. Thereafter, an etchant that can dissolve and remove the thin metal layer 13 is applied to exposed parts of the thin metal layer 13. This process step provides the formation of predetermined first metal interconnects 21, lands 20 for forming external connection terminals, and first marks 19a above the semiconductor substrate 10. These are made of, for example, a Cu film with a thickness of approximately 5 μm.

Next, as shown in FIG. 8B, the entire surface region of the semiconductor substrate 10 is coated with a photosensitive insulating material by spin coating, dried and successively exposed to light and developed. Then, parts of the insulating material located on parts of the first metal interconnects 21 and the lands 20 are selectively removed, thereby forming a second insulating layer 22 having a plurality of openings. The entire surface of each first mark 19a formed across the scribe line 18 to the peripheries of the adjacent element regions is covered with the second insulating layer 22.

Then, as shown in FIG. 8C, second metal interconnects 17 and a second mark 33 are formed by a photolithography process, a thick film formation process using a thick film formation technique such as electrolytic plating, and an etching process. Although Cu that is the same material as the first metal interconnect 21 and the first mark 19a is employed as a metal material of the second metal interconnect 17 and second mark 33, another metal material may be employed thereas.

Subsequently, as shown in FIG. 8D, a third insulating layer 32 is formed to expose the top surfaces of the second metal interconnects 17. The third insulating layer 32 is formed, for example, using an epoxy resin to have a thickness of 20 through 30 μm. In this case, the third insulating layer 32 covers and thus protects the top surface of the lands 20, the side surfaces of the second metal interconnects 17, and the top and side surfaces of the second marks 33. Since the second marks 33 are wholly covered with the third insulating layer 32, this can ensure a sufficiently large adhesive strength between the second mark 33 and the third insulating layer 32. Subsequently, the top surfaces of the second metal interconnects 17 are subjected to an oxidation prevention process, and thereafter external connection terminals 23 are formed thereon. The oxidation prevention process and the external connection terminals 23 are the same as in the first embodiment. Thereafter, an assembly of semiconductor devices is cut along the scribe lines 18 by dicing to obtain individual separated semiconductor devices. In this case, the first mark 19a, the second mark 33, the second insulating layer 22, and the third insulating layer 32 formed across each scribe line 18 to the peripheries of the adjacent element regions are cut and divided together with the semiconductor substrate 10. The remaining region of the scribe line 18 serves as a part of a package. In this way, the mark parts 28a and 28b made of two stacked metals are exposed at a side surface 80 of each semiconductor device. Although these mark parts 28a and 28b are exposed at a side surface of each semiconductor device, the surfaces of the mark parts 28a and 28b other than the exposed surfaces thereof are surrounded by the second insulating layer 22 and the third insulating layer 32. Therefore, there is no possibility that the mark parts 28a and 28b may drop off. In this embodiment, the third insulating layer 32 is placed on the second insulating layer 22, and the external connection terminals 23 are placed on the parts of the second metal interconnects 17 exposed from the third insulating layer 32. However, the combination of the second insulating layer 22 and the third insulating layer 32 may be treated as a second insulating layer.

Each multilayer structure of first and second marks 19a and 33 are formed on a region of the semiconductor substrate 10 extending across the scribe line 18 to the peripheries of the adjacent element regions and result in the two following cases: the case where they remain in the opposed side surfaces of two adjacent semiconductor devices with the scribe line 18 interposed therebetween and are exposed as mark parts 28a and 28b at each of the opposed side surfaces; and the case where they remain only in a side surface of one of two adjacent semiconductor devices and are exposed as mark parts 28a and 28b. This embodiment corresponds to the former case. In this embodiment, two multilayer structures of mark parts 28a and 28b of the same shape and dimensions are formed in the opposed side surfaces of two adjacent semiconductor devices. Furthermore, although in this embodiment the mark parts 28a and 28b are rectangular, they may have an arbitrary shape that can be formed in the photolithography process. In this case, the arbitrary shape must be a shape that can be identified by a visual inspection and an inspecting device. In addition, in all the semiconductor devices, the mark parts 28a and 28b may be formed anywhere in the side surfaces of each semiconductor device.

The embodiments described above are exemplary, and the present invention is not restrictive to these embodiments. For example, the semiconductor device of the present invention can be applied not only to a CSP having a structure in which the second metal interconnects (posts) 17 are formed but also to a CSP having a structure in which only the first metal interconnects 21 are formed without the provision of posts. When it is applied to the latter CSP, the latter CSP has the following structure. The second insulating layer 22 is formed to have openings above the lands 20 for forming external connection terminals, the openings are formed with external connection terminals 23, and thereby electrical connection can be ensured between the external connection terminals 23 and the lands 20.

When mark parts 28 are exposed at a plurality of side surfaces of a single semiconductor device, the mark parts 28 at the different side surfaces thereof may have different shapes and layouts.

The mark parts 28, which expose their cut surfaces at side surfaces of the semiconductor devices separated from one another by dicing and indicates the orientation and product information of the semiconductor devices, never determine the quality of these semiconductor devices.

As described above, in the semiconductor device of the present invention, the formation of a metal layer in a fabrication process results in the provision of a product information indication mark, an orientation mark and the like composed of a plurality of mark parts in predetermined sites of side surfaces of the semiconductor device. This ensures product traceability in accordance with the product information, such as a product number or a lot number, and allows the orientations of the semiconductor devices to be identified, without being affected by the dimensions and shapes of the semiconductor devices and the layouts of the external connection terminals even with significant size reduction in the semiconductor devices.

Furthermore, since the metal layer serving as the mark part is covered with the second insulating layer on its side and top surfaces, this ensures an adhesive strength between the metal layer located in the cut and exposed surface of the semiconductor device and each of the first and second insulating layers. Therefore, the metal layer can be prevented from dropping off due to dicing and metal burr and metal waste can be reduced.

When a large number of semiconductor devices are loaded in a tray, the exposure of mark parts at two parallel side surfaces of each semiconductor device allows the mark parts to be easily read, which allows product information to be read at high speed and allows the semiconductor devices to be sorted in a short time.

When the metal layer forming the mark part is electrically connected to the element electrode of the semiconductor device, it can also be utilized as a heat dissipating system as follows. Heat produced during the operation of an integrated circuit is dissipated from the element electrode through the mark part exposed at a side surface of the semiconductor device to the outside. In addition, it can be used as a test terminal for electrically testing a PCM (Process Control Module) for checking a wafer-level CSP for the connection reliability between the metal interconnect and the element electrode and the interconnect reliability of the metal interconnect in a CSP fabricating process. This eliminates the need for forming additional external connection terminals necessary for electrically checking the CSP for the connection reliability between the metal interconnects and the element electrode and the interconnect reliability of the metal interconnect and does not exert an influence on the number of the external connection terminals.

When a stepped extension is provided at the side surfaces of the semiconductor device and the mark part is exposed at both the surfaces of the semiconductor device parallel and vertical to the semiconductor substrate, the mark part can be identified not only from a side surface of the semiconductor device but also from the surface of the semiconductor device on which external connection terminals are formed or the opposite surface thereof. That is, the mark part can be identified from two surfaces of the semiconductor device. Therefore, the mark part can easily be identified at high speed. Furthermore, if a plurality of metal layers constituting mark parts and a plurality of insulating layers are stacked, a mark, such as a bar code, including a lot of product information can be formed.

In the semiconductor device fabricating method of the present invention, the semiconductor device can easily be fabricated by a small number of process steps, and the known process step for forming a mark indicating the orientation of the semiconductor device, a product number and a lot number can be omitted. Furthermore, when a metal layer serving as a mark part is formed simultaneously with the formation of a metal interconnect layer, the number of photolithography process steps is the same as that of the known photolithography process steps. This does not lead to increase in the number of fabrication process steps. The mark part can maintain high positional accuracy and high dimensional accuracy as long as the metal layer is formed in possible sites to have formable shapes.

What is claimed is:

1. A semiconductor device comprising:
a semiconductor substrate;
an element electrode formed on the top surface of the semiconductor substrate;
a first insulating layer formed on the semiconductor substrate to have an opening at least on the element electrode;
a metal interconnect layer formed to cover the top surface of the element electrode and a part of the first insulating layer to extend from the element electrode partway across the first insulating layer;
a second insulating layer formed above the semiconductor substrate with the exception of the surfaces of parts of the metal interconnect layer; and
external connection terminals formed on parts of the metal interconnect layer exposed from the second insulating layer,
wherein a plurality of mark parts made of metal are exposed at one or some of the side surfaces of the semiconductor device generally vertical to the top surface of the semiconductor substrate, the parts of the side surfaces of the semiconductor device being composed of the second insulating layer.

2. The semiconductor device of claim 1, wherein
the plurality of mark parts constitute identification symbols of the semiconductor device.

3. The semiconductor device of claim 1, wherein
the mark parts are exposed at two of the side surfaces of the semiconductor device parallel to each other.

4. The semiconductor device of claim 1, wherein
an extension is provided at the side surfaces of the semiconductor device to project vertically to the side surfaces, and
the mark part is exposed also at the surface of the extension vertical to the side surfaces of the semiconductor device.

5. The semiconductor device of claim 1, wherein
the mark part is electrically connected to the element electrode.

6. The semiconductor device of claim 1, wherein
at least some of the mark parts form layered metal parts which are different from one another in distance from the top surface of the semiconductor device.

7. A method for fabricating a semiconductor device, said method comprising:
the step S of forming a first insulating layer on the top surface of a semiconductor substrate in the form of a wafer on which an element electrode is formed and removing a part of the first insulating layer located on the element electrode;
the step T of forming a metal interconnect layer to cover the top surface of the element electrode and a part of the first insulating layer;
the step U of forming a metal layer serving as mark parts to each extend across a scribe line to the ends of adjacent element regions of the semiconductor substrate;
the step V of, after the steps T and U, forming a second insulating layer on the entire surface region of the semiconductor substrate and removing parts of the second insulating layer located on the surfaces of parts of the metal interconnect layer;
the step W of forming external connection terminals on the surfaces of the parts of the metal interconnect layer exposed by removing the parts of the second insulating layer; and
the step X of cutting the semiconductor substrate along each said scribe line to obtain individual semiconductor devices.

8. The method for fabricating a semiconductor device of claim 7, wherein
in the step U, each said metal layer is formed to expose a plurality of said mark parts at at least one cut surface of the semiconductor device separated in the step X.

9. The method for fabricating a semiconductor device of claim 7, wherein
the step T is carried out simultaneously with the step U.

10. The method for fabricating a semiconductor device of claim 7, wherein
the step X comprises:
the substep X1 of cutting the second insulating layer along the scribe line at a first width until the metal layer is exposed; and
the substep X2 of cutting, at a second width narrower than the first width, along the center line of the exposed surface of the metal layer obtained by cutting the second insulating layer at the first width until the semiconductor substrate is cut through.

11. The method for fabricating a semiconductor device of any one of claims 7 through 10, wherein
in the steps U and V, a plurality of metal layers are formed to interpose the second insulating layer between the adjacent metal layers.
